(19) United States
(12) Patent Application Publication
(10) Pub. No.: US 2008/0047731 A1
(43) Pub. Date: Feb. 28, 2008

(54) COVER PLATES FOR OUTLET BOXES AND THE METHOD OF USING THE COVER PLATES IN THE INSTALLATION OF WALL COVERINGS

(76) Inventors: Torsten Krueger, Hamilton (CA); George Jaic, Stoney Creek (CA)

Correspondence Address: Mark A. Koch;Professional Corporation, 583 Main Street East, Hamilton, ON, L8M 1J4, US

(21) Appl. No.: 11/843,001

(22) Filed: Aug. 22, 2007

Related U.S. Application Data
(60) Provisional application No. 60/823,544, filed on Aug. 25, 2006.

(51) Int. Cl. H05K 5/03

(52) U.S. Cl. 174/67

(57) ABSTRACT

A cover plate for use with an electrical box, the cover plate comprising a substantially planar cover including a front face, a back face and a cover outer periphery; a spike rigidly connected to the plate and projecting perpendicularly from the front face of the cover; wherein the spike is adapted to penetrate through and perforate a wall covering which is urged against the spike; and devices for removeably fastening the cover plate to the electrical box. Optionally wherein the fastening devices including fastener apertures positioned and dimensioned to receive screws there through for removeably fastening to the electrical box. Optionally wherein the spike being welded to the cover.

### FIELD OF THE INVENTION

This application claims priority from previously regularly filed U.S. provisional application filed Aug. 25, 2006 under application No: 60/823,544 titled COVER PLATES FOR OUTLET BOXES AND THE METHOD OF USING THE COVER PLATES IN THE INSTALLATION OF WALL COVERINGS by Torsten Krueger and George Jaic.

The present invention relates to cover plates for outlet boxes and the method of using the cover plates in the installation of wall coverings.

### BACKGROUND OF THE INVENTION

In present construction techniques, studs are used to free form wall studs which are located in buildings. Electrical wires, plumbing etc., is installed through the wall prior to the application of the surface covering which normally is drywall and/or some type of wall panelling. In many cases, outlet boxes such as electrical outlet boxes, plumbing outlet boxes and/or other device outlet boxes are pre-installed between the studding in the walls prior to the application of the covering material such as the drywall and/or the wall panelling.

After the drywall or the wall panelling has been installed onto the studding the contractor must recall the location of the various outlet boxes which are attached to the studding in order to then cut out holes in the drywall or the panelling in order to uncover the outlet boxes.

The rest of this description will describe an apparatus and method for improving this construction technique.

### SUMMARY OF THE INVENTION

A cover plate for use with an electrical box, said cover plate comprising:
a) a substantially planar cover including a front face, a back face and a cover outer periphery;
b) a spike rigidly connected to the plate and projecting perpendicularly from the front face of the cover; wherein the spike is adapted to penetrate through and perforate a wall covering which is urged against the spike;
c) a means for removeably fastening the cover plate to the electrical box.

The cover plate wherein the fastening means including fastener apertures positioned and dimensioned to receive screws there through for removeably fastening to the electrical box.

The cover plate wherein the spike being welded to the cover.

The cover plate wherein the spike being a portion of the cover which is partially stamped or cut out of the cover and oriented to project perpendicularly from the front face of the cover.

The cover plate wherein the cover outer periphery being somewhat larger than the electrical box outer periphery.

The cover plate wherein the wall covering being drywall and the spike dimensioned and adapted to easily penetrate through drywall.

A system of locating electrical boxes and cutting out openings in wall coverings during construction of walls, the system comprising;
a) installing cover plates onto electrical boxes which are mounted onto framing studs, wherein the cover plates include;
   i) a substantially planar cover including a front face, a back face and a cover outer periphery,
   ii) a spike rigidly connected to the plate and projecting perpendicularly from the front face of the cover; wherein the spike is adapted to penetrate through and perforate the wall covering which is urged against the spike,
   iii) a means for removeably fastening the cover plate to the electrical box.
b) installing wall covering onto the studs such that the spikes penetrate through the wall covering thereby revealing the location of the electrical boxes.

The system of locating electrical boxes and cutting out openings in wall coverings during construction of walls wherein the wall covering being drywall.

The system of locating electrical boxes and cutting out openings in wall coverings during construction of walls further including cutting out portions of the wall covering which cover over the electrical box with a cutting tool wherein the cutting tool following the cover outer periphery to ensure the electrical box is exposed from behind the wall covering.

The system of locating electrical boxes and cutting out openings in wall coverings during construction of walls further including removing the cover plates from the electrical boxes.

### BRIEF DESCRIPTION OF THE DRAWINGS

The invention will now be described by way of example only with reference to the following drawings in which:

FIG. 1 is a schematic front perspective view of an electrical box shown deployed onto a stud shown in dashed lines.

FIG. 2 is a schematic front assembly perspective view of an electrical box shown with a cover plate not installed with the electrical box mounted on to a vertical stud.

FIG. 3 is a front plan view of the cover plate.

FIG. 4 is a side elevation view of the cover plate.

FIG. 5 is a end elevation view of cover plate.

FIG. 6 is a front schematic perspective view of the cover plate.

FIG. 7 is a back schematic perspective view of the cover plate.

FIG. 8 is a schematic of an electrical box installed onto a stud wherein drywall has been installed onto the studs such that the spike perforates through the drywall and through the front side of the drywall.

FIG. 9 is a plan view of an alternate embodiment of a cover plate.

FIG. 10 is a side elevation view of the cover plate shown in figure nine.

FIG. 11 is a front perspective assembly view of an electrical box with the cover plate shown in figure nine.

### DETAILED DESCRIPTION OF THE PREFERRED EMBODIMENT

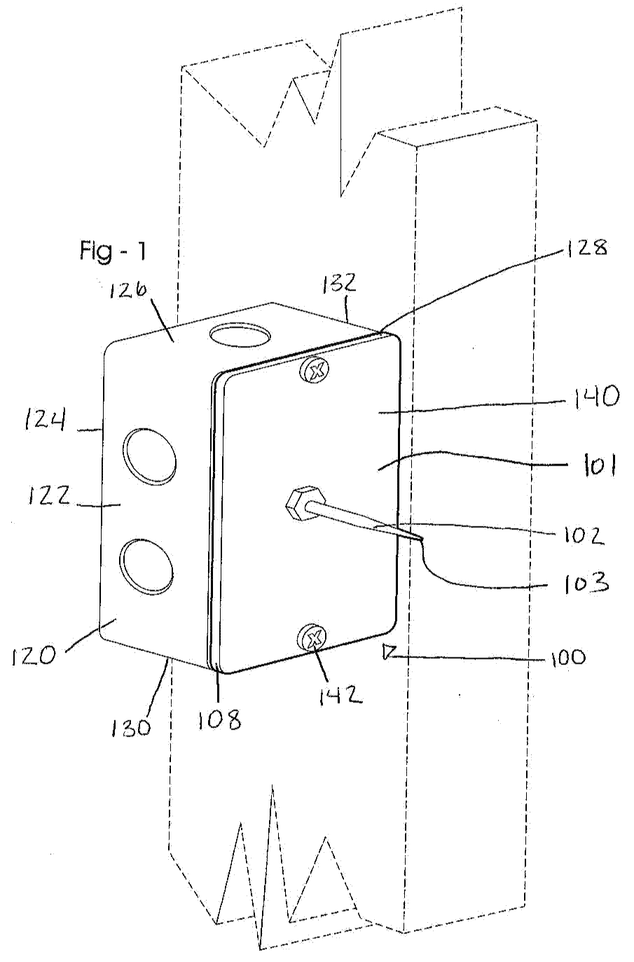

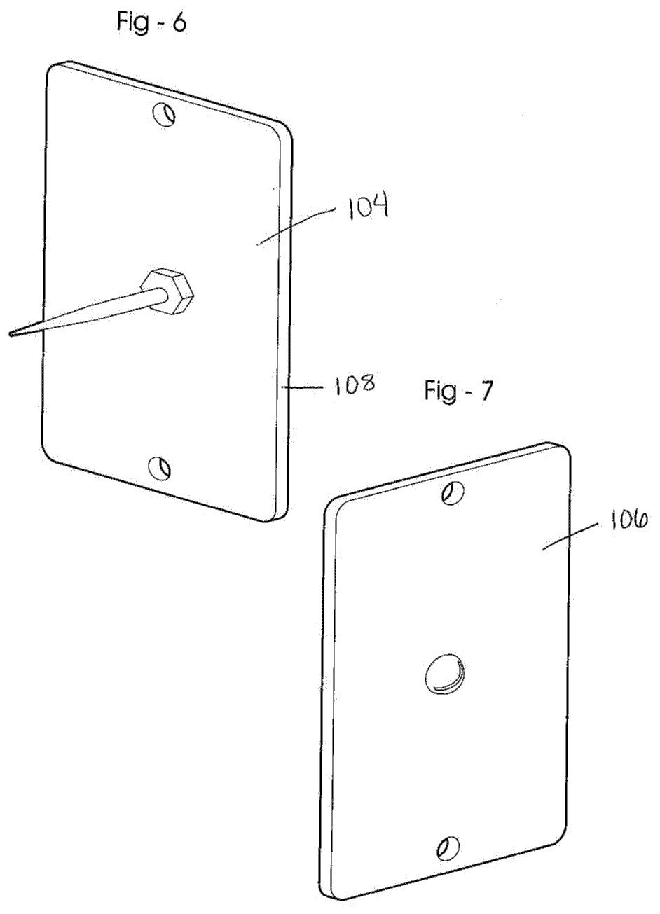

A cover plate for wall outlet boxes and method of using tie same is described and depicted in FIGS. 1 through 11 and is shown generally as 100 in FIG. 1 for example.

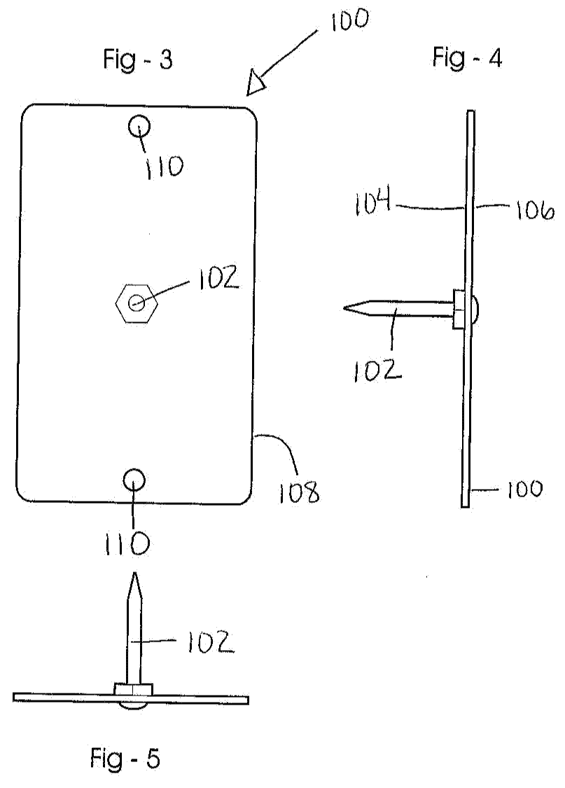

Referring now specifically to FIGS. 3, 4 and 5, cover plate 100, a substantially planar cover 101, a spike 102, having a sharp point 103, cover 101 including a front face 104, a back face 106 an outer periphery 108 and fastener apertures 110.

Cover plate 100 is shown installed onto an electrical box 120 in FIG. 1 for example. The electrical box 120 includes a left side 122, a backside 124, a top 126, a front side 128, a bottom 130, a right side 132 and fastener holes 134.

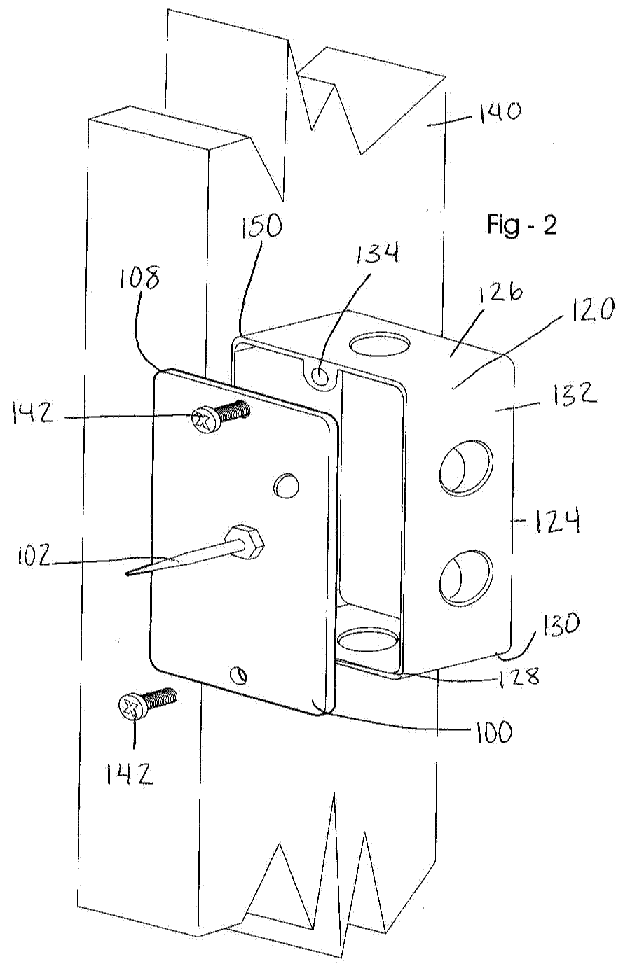

Electrical box 120 is fastened to the side of a stud 140 as depicted in FIG. 1 and/or in FIG. 2.

In these Figures, the wall outlet boxes are electrical boxes, however the wall outlet boxes may also be other types of outlet boxes which are used in residential and/or commercial building construction. Electrical outlet boxes are shown as an example only and for ease of understanding by the reader.

Cover plate 100 is screwed onto electrical box 120 using screws 142 which are screwed into fastener holes 134 which are normally found on ordinary electrical boxes 120. There may be other methods and/or means of attaching cover plate 100 onto electrical box 120, however for this example we are using the existing fastener holes 134 and screws 142 to attach cover plate 100 onto electrical box 120.

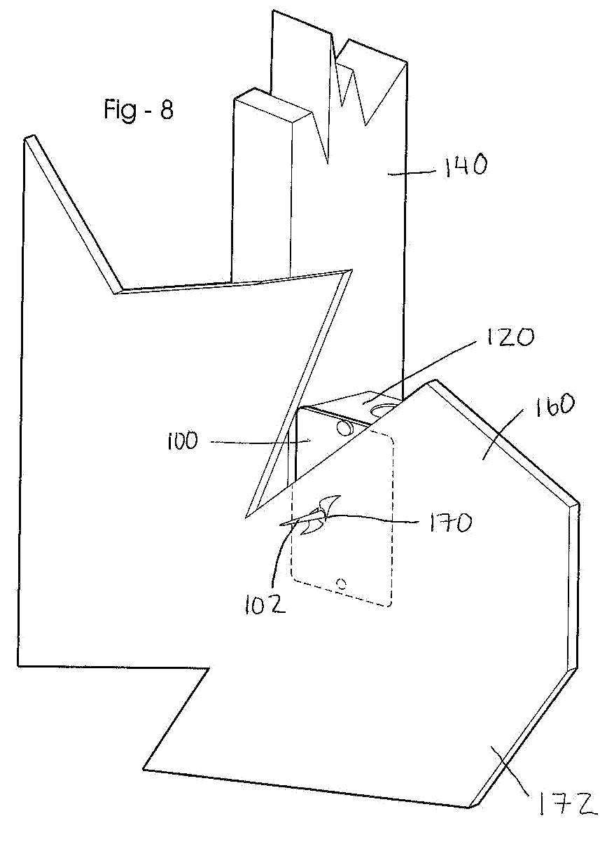

The reader will note that electrical box 120 also has a box outer periphery 150 which is slightly smaller in dimension than cover outer periphery 108. With cover plate 100 in place including spike 102, drywall 160 as shown in FIG. 8 is installed onto studs 140 in order to produce smooth wall covering along the vertically oriented studs. A person skilled in the art will note that drywall 160 may also be some type of panelling and/or a variety of wall coverings that are available for placing onto and attaching to a studded wall.

As can be seen in FIG. 8, spike 102 penetrates and perforates drywall 160 at perforation 170, projecting through drywall 160 and out the front side 172 of drywall 160.

Therefore, once drywall 160 is in place, the installer will note the locations of spikes 102 and immediately be able to determine the location of the electrical box 120 in behind drywall 160.

The contractor will normally urge a router into drywall 160 until it hits cover plate 100. The contractor will then move the router bit until it moves off of outer periphery 106 of cover plate 100 and subsequently the router will be manipulated to cut drywall 160 as the bit is guided by outer periphery 106 of the cover plate. Alternately the contractor may measure off the known distance from the spike to the cover outer periphery 106 and place the cutting tool at that location, wherein while cutting the drywall 160, the cutting tool will be guided by the cover outer periphery 108 and therefore provide the proper sized hole in order to reveal electrical box 120. Preferably the cover outer periphery 108 being somewhat larger than the electrical box outer periphery 150 to ensure that electrical box 120 is not damaged by the cutting tool.

Cover plate 100 is normally left in place until final mudding, sanding, painting etc. has been carried out on the front side 172 of drywall 160, thereby further protecting the interior portion of electrical box 120 from the entrance of drywall mud, dust etc.

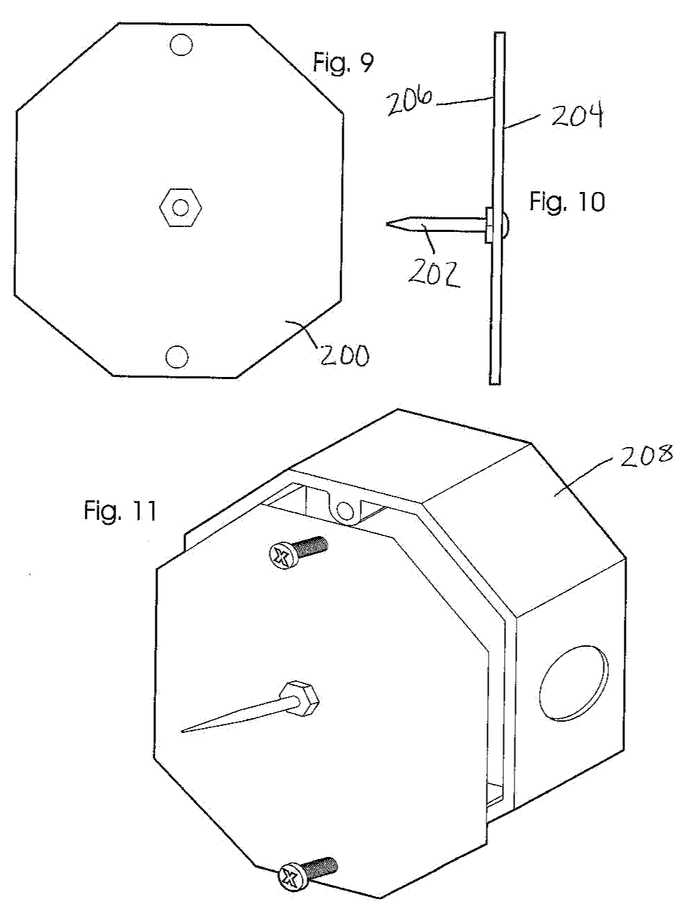

FIGS. 9, 10 and 11 show an alternate shape of cover plate shown generally as 200. Cover plate 200 also has a spike 202, a back face 204, a front face 206 and covers electrical box 208. In this example, a hexagonal electrical box 208 is covered with a hexagonal cover plate 200.

A person skilled in the art will note that any shape of cover plate 100 or 200 is possible including round shapes, hexagonal, square, rectangular, triangular etc. The shape of the cover plate is determined by the shape of the wall outlet box that it is covering and is designed in such a manner that a spike 102 is positioned in order to penetrate through the wall covering, whether it be drywall, panelling or any other kind of wall covering material.

Once the wall is substantially complete, the cover plate 100 can easily be removed from electrical box 120, by unfastening screws 142 from fastener holes 134. Thereafter the further installation of wires etc. in electrical box 120 can be completed.

1. A cover plate for use with an electrical box; said cover plate comprising:
a) a substantially planar cover including a front face, a back face and a cover outer periphery;
b) a spike rigidly connected to the plate and projecting perpendicularly from the front face of the cover; wherein the spike is adapted to penetrate through and perforate a wall covering which is urged against the spike;
c) a means for removeably fastening the cover plate to the electrical box.

2. The cover plate claimed in claim 1 wherein the fastening means including fastener apertures positioned and dimensioned to receive screws there through for removeably fastening to the electrical box.

3. The cover plate claimed in claim 1 wherein the spike being welded to the cover.

4. The cover plate claimed in claim 1 wherein the spike being a portion of the cover which is partially stamped or cut out of the cover and oriented to project perpendicularly from the front face of the cover.

5. The cover plate claimed in claim 1 wherein the cover outer periphery being somewhat larger than the electrical box outer periphery.

6. The cover plate claimed in claim 1 wherein the wall covering being drywall and the spike dimensioned and adapted to easily penetrate through drywall.

7. A system of locating electrical boxes and cutting out openings in wall coverings during construction of walls, the system comprising;
a) installing cover plates onto electrical boxes which are mounted onto framing studs, wherein the cover plates include;
i) a substantially planar cover including a front face, a back face and a cover outer periphery,
ii) a spike rigidly connected to the plate and projecting perpendicularly from the front face of the cover; wherein the spike is adapted to penetrate through and perforate the wall covering which is urged against the spike,
iii) a means for removeably fastening the cover plate to the electrical box,
b) installing wall covering onto the studs such that the spikes penetrate through the wall covering thereby revealing the location of the electrical boxes.

8. The system of locating electrical boxes and cutting out openings in wall coverings during construction of walls claimed in claim 7 wherein the wall covering being drywall.

9. The system of locating electrical boxes and cutting out openings in wall coverings during construction of walls claimed in claim 7 further including cutting out portions of the wall covering which cover over the electrical box with a cutting tool wherein the cutting tool adapted to follow the contour of the cover outer periphery to ensure the electrical box is exposed from behind the wall covering.

10. The system of locating electrical boxes and cutting out openings in wail coverings during construction of walls claimed in claim 7 further including removing thee cover plates from the electrical boxes.
